(19) United States
(12) Patent Application Publication
(10) Pub. No.: US 2018/0374972 A1
(43) Pub. Date: Dec. 27, 2018

(54) CHARGE EXTRACTION DEVICES, SYSTEMS, AND METHODS

(71) Applicant: The Regents of the University of California, Oakland, CA (US)

(72) Inventors: Oscar Vazquez Mena, La Jolla, CA (US); Wenjun Chen, La Jolla, CA (US)

(21) Appl. No.: 16/016,407

(22) Filed: Jun. 22, 2018

Related U.S. Application Data
(60) Provisional application No. 62/524,155, filed on Jun. 23, 2017.

(51) Int. Cl. H01L 31/0352; H01L 31/0296; H01L 31/032; H01L 31/0336

(52) U.S. Cl. CPC H01L 31/035218; H01L 31/0336; H01L 31/0324; H01L 31/0296

(57) ABSTRACT

A composite film structure having a first absorbing layer comprising a first material, a second absorbing layer comprising a second material, and a first collector layer disposed between the first absorbing layer and the second absorbing layer, wherein the first absorbing layer has a thickness that is less than a diffusion length of a photocarrier of the first material, and wherein the second absorbing layer has a thickness that is less than a diffusion length of a photocarrier of the second material.

### CLAIM OF PRIORITY

This application claims the benefit of U.S. Provisional Patent Application No. 62/524,155, filed on Jun. 23, 2017, the entire contents of the foregoing are hereby incorporated by reference.

### STATEMENT AS TO FEDERALLY SPONSORED RESEARCH

This invention was made with government support under ECCS-1710472 awarded by the NSF. The government has certain rights in the invention.

### TECHNICAL FIELD

This invention relates to charge extraction devices, systems, and methods, and more particularly, to composite film structures for charge extraction.

### BACKGROUND

Photocarriers are collected in photodetectors and photovoltaics for applications in communications, imaging technologies, biosensing, medical instruments, and energy harvesting.

### SUMMARY

Disclosed are methods, materials, articles of manufacture, and devices that pertain to an architecture for radiation (e.g., electromagnetic radiation) absorbing layers intercalated with one or more collector layers as current extractors. In some embodiments, the absorbing layers can be quantum dot (QD) based absorbing layers. In some embodiments, the collector layers can be graphene (Gr). Disclosed herein is a composite film structure including absorbing layers based on one or more intercalated collector (e.g., graphene) layers as current extractors. In some embodiments, collector layers are stacked between absorbing layers such that the spacing between the collector layers is shorter than a diffusion length of a photocarrier (L_{D}) of about 200 to about 300 nm. In some embodiments, a spacing between the collector layers of about 200 to about 300 nm can exhibit efficient charge collection in the visible range. In some embodiments, the intercalated Gr/QD devices exhibit a much higher photoresponse than single Gr/QD devices. In some examples, the intercalated Gr/QD devices can be operated in the low bias regime that is compatible with silicon integrated circuits. The intercalated Gr/QD devices disclosed herein may represent a new class of high light absorption and efficient charge collection devices.

In one aspect, a composite film structure is provided, having a first graphene layer, a first layer that includes a first material disposed on the first graphene layer; and a second graphene layer disposed on the first layer. The first layer has a thickness that is less than a diffusion length of a photocarrier of the first material.

Implementations can include one or more of the following features. The first material can be configured to generate photocarriers when exposed to electromagnetic radiation. The first material can include quantum dots. The quantum dots can include PbS nanoparticles. The diffusion length of a photocarrier can be about 200-300 nm. The thickness of the first layer can be about 20 nm. The composite film structure can include a second layer of the first material disposed on the second graphene layer. The second layer can have a thickness that is less than the diffusion length of a photocarrier of the first material. A photodetector can include a composite film structure. The first graphene layer and the second graphene layer can be configured to be current extractors. The photodetector can be configured to operate in a low bias regime. A second layer of the first material can be disposed on the second graphene layer. The second layer can have a thickness that is less than the diffusion length of a photocarrier of the first material. The photodetector can have a sensitivity of at least 1×10⁷ A/W at an irradiation of 1×10⁻⁵ mW/cm². The first graphene layer and the second graphene layer can be configured as parallel conductive channels.

In another aspect, a method of forming a composite film structure is provided, including transferring a first layer of graphene onto a substrate, spin-coating a layer of a first material on the first layer of graphene, and transferring a second layer of graphene onto the layer of the first material. A thickness of the layer of the first material can be less than a diffusion length of the first material.

Implementations can include one or more of the following features. The method can include growing the graphene by chemical vapor deposition. The thickness of the layer of the first material is about 20 nm. The method can include surface ligand modification after the layer of the first material is spin-coated on the first layer of graphene. The first material can include quantum dots. The quantum dots can include PbS nanoparticles. A method of fabricating a photodetector can include forming the composite film structure where the first graphene layer and the second graphene layer are configured to be current extractors. The graphene layers can be configured as parallel conductive channels.

In one aspect, the disclosure provides composite film structure, the composite film structure comprising: a first absorbing layer comprising a first material; a second absorbing layer comprising a second material; and a first collector layer disposed between the first absorbing layer and the second absorbing layer; wherein the first absorbing layer has a thickness that is less than a diffusion length of a photocarrier of the first material, and wherein the second absorbing layer has a thickness that is less than a diffusion length of a photocarrier of the second material.

These and other implementations can optionally further include one or more of the following features. A least one of the first material and the second material can be configured to generate photocarriers when exposed to electromagnetic radiation. At least one of the first material and the second material can comprise quantum dots. The quantum dots can comprise PbS nanoparticles. The quantum dots can comprise ZnO nanoparticles. The quantum dots can comprise CdSe nanoparticles. The first material comprises PbS nanoparticles and the second material can comprise ZnO nanoparticles. The diffusion length of a photocarrier of at least one of the first material and the second material can be about 200 to about 300 nm. The thickness at least one of the first absorbing layer and the second absorbing layer can be about 5 to about 500 nm. The thickness of at least one of the first absorbing layer and the second absorbing layer can be about 15 to about 30 nm. The first collector layer can comprise graphene. The first absorbing layer can be disposed between the first collector layer and a primary collector layer. The primary collector layer can be disposed between the first absorbing layer and a substrate. The primary collector layer can comprise graphene. The substrate can be selected from the group consisting of SiO2, Si, and combinations thereof. The first material and the second material can be the same material. The first material and the second material can be different materials. The second absorbing layer can be disposed between the first collector layer and a second collector layer. The second collector layer can be disposed between the second absorbing layer and a third absorbing layer comprising a third material, and wherein the third collector layer has a thickness that is less than the diffusion length of a photocarrier of the third material. The diffusion length of a photocarrier of the third material can be about 200 to about 300 nm. The thickness of the third absorbing layer can be about 5 to about 500 nm. The thickness of the third absorbing layer can be about 15 to about 30 nm. The composite film structure can further comprise a second absorbing layer; n absorbing layers each independently comprising a third material; and m collector layers, wherein the second collector layer is disposed between the second absorbing layer and the a first of the n absorbing layers, wherein the n absorbing layers and the m collector layers are alternatingly disposed such that each of the m collector layers is positioned between and directly contacting two absorbing layers, wherein each of the n absorbing layers independently has a thickness that is less than a diffusion length of a photocarrier of the respective third material, wherein n equals at least 1, wherein m equals n−1, and wherein n is less than or equal to 20. The first material, the second material, the third material, or combinations thereof can be configured to generate photocarriers when exposed to electromagnetic radiation. Two or more of the n absorbing layers can comprise different materials. Two or more of the n absorbing layers can comprise the same material. All of the n absorbing layers can comprise the same material. One or more of the m collector layers comprise graphene. The first material, the second material, the third material, or combinations thereof can comprise quantum dots. The diffusion length of a photocarrier of the first material, the second material, the third material, or combinations thereof can be about 200 to about 300 nm. The thickness of the each of the n absorbing layers, independently, can be about 5 to about 500 nm. The thickness of each of then layers, independently, can be about 15 to about 30 nm.

In another aspect, this disclosure provides a photodetector comprising the composite film structure of claim 1, wherein the first collector layer is configured to be a current extractor.

These and other implementations can optionally further include one or more of the following features. The photodetector can be configured to operate in a low bias regime. The second absorbing layer can be disposed between the first collector layer and a second collector layer. The first collector layer and the second collector layer can be configured to operate as parallel conductive channels At least one of the first collector layer and the second collector layer can comprise graphene. The first absorbing layer can be disposed between the first collector layer and a primary collector layer. The first collector layer, the second collector layer, and the primary collector layer can be configured to operate as parallel conductive channels. The primary collector layer can be disposed between the first absorbing layer and a substrate. The photodetector can have a sensitivity of at least 1×107 A/W at an irradiation of 1×10−5 mW/cm2. The photodetector can further comprise a second collector layer; n absorbing layers each independently comprising a third material; and m collector layers, wherein the second collector layer is disposed between the second absorbing layer and a first of the n absorbing layers, wherein the n absorbing layers and the m collector layers are alternatingly disposed such that each of the m collector layers is positioned between and directly contacting two absorbing layers, wherein the each of the n absorbing layers has a thickness that is less than a diffusion length of a photocarrier of the third material, wherein n equals at least 1, wherein m equals n, and wherein n is less than or equal to 20.

In another aspect, this disclosure provides method of forming a composite film structure, the method comprising: spin-coating a first absorbing layer comprising a first material on a primary layer; transferring a first collector layer onto the first absorbing layer; and spin-coating a second absorbing layer comprising a second material on the first collector layer, wherein a thickness of the first absorbing layer of the first material is less than a diffusion length of a photocarrier of the first material, and a thickness of the second absorbing layer of the second material is less than a diffusion length of a photocarrier of the second material.

These and other implementations can optionally further include one or more of the following features. The method can further comprise transferring a second collector layer onto the second absorbing layer. The primary layer can be a primary collector layer. The primary layer can be a substrate. The method can further comprise growing the first collector layer by chemical vapor deposition. The thickness of one or more of the first absorbing layer and the second absorbing layer can be about 5 to about 500 nm. The thickness of one or more of the first absorbing layer and the second absorbing layer can be about 15 to about 25 nm. The method can further comprise modifying the first absorbing layer with surface ligand modification after the first absorbing layer is spin-coated on the primary layer. The method can further comprise modifying the second absorbing layer with surface ligand modification after the second absorbing layer is spin-coated on the first graphene layer. The at least one of first material and the second material can comprise quantum dots. The quantum dots are selected from the group consisting of PbS nanoparticles, ZnO nanoparticles, or CdSe nanoparticles.

In another aspect, this disclosure provides a method of fabricating a photodetector, the method comprising forming the composite film structure according to any of the methods described herein, wherein the first collector layer is configured to be a current extractor.

In another aspect, this disclosure provides a method of fabricating a photodetector, the method comprising forming the composite film structure according to any of the methods described herein, and wherein the first collector layer and the second collector layer are configured to be current extractors.

These and other implementations can optionally further include one or more of the following features. The first collector layer and the second collector layer can be configured as parallel conductive channels.

In another aspect, this disclosure provides a composite film structure, the composite film structure comprising: n absorbing layers each independently comprising a first material; and m collector layers, wherein the n absorbing layers and the m collector layers are alternatingly disposed such that each of the m collector layers is positioned between and directly contacting two absorbing layers, wherein each of the n absorbing layers independently has a thickness that is less than a diffusion length of a photocarrier of the respective first material, wherein n is at least 2, wherein m is n−1, and wherein n is less than or equal to 20.

These and other implementations can optionally further include one or more of the following features. The composite film structure can further comprise a primary layer, the n absorbing layers and m collector layers being disposed thereon. The primary layer can comprise a second material. The primary layer can have a thickness that is less than a diffusion length of a photocarrier of the second material. The primary layer can comprise a substrate. The substrate can be selected from the group consisting of SiO2, Si, and combinations thereof.

In another aspect, this disclosure provides a composite film structure, the composite film structure comprising: from 1 to 20 collector layers, each independently disposed between and directly contacting two absorbing layers, wherein each absorbing layer independently comprises a material, and wherein each absorbing layer has a thickness that is less than a diffusion length of a photocarrier of the respective material.

The systems and methods described herein can provide several advantages. Potential benefits of some embodiments of devices and methods disclosed herein can include decoupling of light absorption from charge separation, high light absorption and efficient charge separation, enhancement of photodetector sensitivity across some or all spectral regimes, or compatibility with low temperature processing and/or large area integration. Potential commercial applications of the composite film structures and photodetectors described herein include light detecting systems, imaging cameras, and motion detecting systems. Light detectors disclosed herein can advantageously increase the amount of photons that can be converted into electrons for photodetection.

The details of one or more embodiments of the invention are set forth in the accompanying drawings and the description below. Other features, objects, and advantages of the invention will be apparent from the description and drawings, and from the claims.

### DESCRIPTION OF DRAWINGS

The patent or application file contains at least one drawing executed in color. Copies of this patent or patent application publication with color drawing(s) will be provided by the Office upon request and payment of the necessary fee.

FIG. 1A is a side view of an exemplary thin layer single collector layer/absorbing layer (e.g., Gr/QD) system.

FIG. 1B is a side view of an exemplary thick layer single collector layer/absorbing layer (e.g., Gr/QD).

FIG. 1C is a side view of an exemplary intercalated collector layer/absorbing layer (e.g., Gr/QD) system.

FIG. 2A is a graph showing the theoretical behavior of a single Gr/QD system and an intercalated Gr/QD system as the thickness increases.

FIG. 2B is a plot of the conductivity and photoresponse of exemplary devices having a single QD/Gr configuration, a QD/Gr/QD, and a QD/Gr/QD/Gr/QD configuration.

FIG. 2C is a plot of the conductivity for exemplary devices versus the number of QD layers.

FIG. 2D is a plot of the photocurrent for exemplary intercalated and non-intercalated devices. The x-axis shows the number of QD layers.

FIG. 3A is a plot of the photocurrent for non-intercalated devices, displaying a reduced photocurrent in most wavelengths when comparing 1 and 10 layers of quantum dots. (Black and Red-dashed lines).

FIG. 3B is a plot of the photocurrent for intercalated and non-intercalated devices.

FIG. 3C is a plot of the responsivity of non-intercalated devices.

FIG. 4 is a plot of the responsivity and incident power dependence for intercalated devices having varying numbers of QD layers.

FIG. 5A is a plot of the responsivity of devices including PbS nanoparticles with a band gap of 1.2 eV.

FIG. 5B is a plot of the responsivity of devices including PbS nanoparticles with a band gap of 0.8 eV.

FIG. 5C is a plot of the responsivity of devices including ZnO nanoparticles.

FIG. 5D is a plot of the responsivity of devices including CdSe nanoparticles.

FIG. 6 is a plot of the photocurrent devices with PbS nanoparticles with a band gap of 1.2 eV (“1000 nm PbS”), PbS nanoparticles with a band gap of 0.8 eV (“1400 nm PbS”), and CdSe nanoparticles.

FIG. 7 is a plot of the responsivity of devices with channel lengths of 100 μm, 200 μm, and 500 μm.

FIG. 8 is a side view of an exemplary multicolor photodetector.

Like reference symbols in the various drawings indicate like elements.

### DETAILED DESCRIPTION

Photocarrier generation and collection is useful in many applications, such as photosensing. Applicability, sensitivity, and/or efficiency may depend on conversion performance (e.g., the fraction of charge carriers collected). Even a strong photocarrier generation in an absorbing layer may not result in high conversion performance if the photocarriers are not efficiently collected at the electrodes. Diffusion length of a photocarrier of an absorbing layer material can be calculated, for example, as L_{D}=sqrt(Dτ), where D is the diffusivity in m²/s and τ is the lifetime of the photocarrier in seconds. The diffusion length of a photocarrier of an absorbing layer material can affect photocharge collection. For efficient current collection with single top or bottom collector layers (e.g., contacts), the thickness of the absorbing layers should generally not exceed the carrier diffusion length (L_{D}). Otherwise, charges can recombine before reaching the electrode(s). Long L_{D} (100 μm) in crystalline materials like Si can allow efficient collection of charges at top or bottom charge collectors (e.g., contacts) in thick absorbing layers. Lower cost materials such as amorphous or nanocrystal films have much shorter L_{D}, which can limit their photo-response and energy conversion performance. In particular, the short L_{D} in semiconducting quantum dots (QDs) films can prevent higher performing devices despite their extraordinary optical properties, such as size-tunable direct band gap and strong absorption coefficient. The short L_{D} of QDs (L_{D}˜200-300 nm) is comparable to their absorption depth (α) for visible light (α_{VIS}-100-400 nm) and well shorter than near infrared (α_{NIR}˜0.7-1 micron). Since the short L_{D} can limit the thickness of QD films to the 200-300 nm range, a significant amount of photons in the visible, but mainly in the near-IR, are not absorbed and are wasted. Improving the diffusion length of QDs can, in some embodiments, improve charge collection and boost the performance of QD-based optoelectronic devices.

Some QDs have optical properties based on their size-tunable band gap and low processing cost and have allowed the realization of photodetectors and solar cells. QDs can have further properties such as flexible substrate compatibility, a high carrier generation due to a direct band gap, and chemical tunable properties via ligand exchange. However, QDs have a short diffusion length and low mobility of charge. Using a top-gate, extremely fast responses have been achieved with some non-intercalated devices. Some non-intercalated devices work with a bottom electrode configuration. In some exemplary non-intercalated devices, a single bottom electrode configuration limits the absorbing layer to 200-300 nm in thickness, due to the short diffusion length of charge carriers in QD films, therefore also limiting the photoresponse of the devices. This disclosure includes a strategy to overcome the low mobility of charge carriers in QD films through the use of QD films as sensitizer with high conductive systems such as graphene (Gr), 2D semiconductors, and Si. In some examples, the combination of Gr/QD into a hybrid device complemented the properties two nanomaterials by splitting the tasks: QDs absorb light and generate photocharges (e.g., electrons and/or holes), while graphene takes care of charge collection for efficient transport. Some devices disclosed herein have achieved high responsivities with both exfoliated and chemical vapor diffusion (CVD) graphene layers.

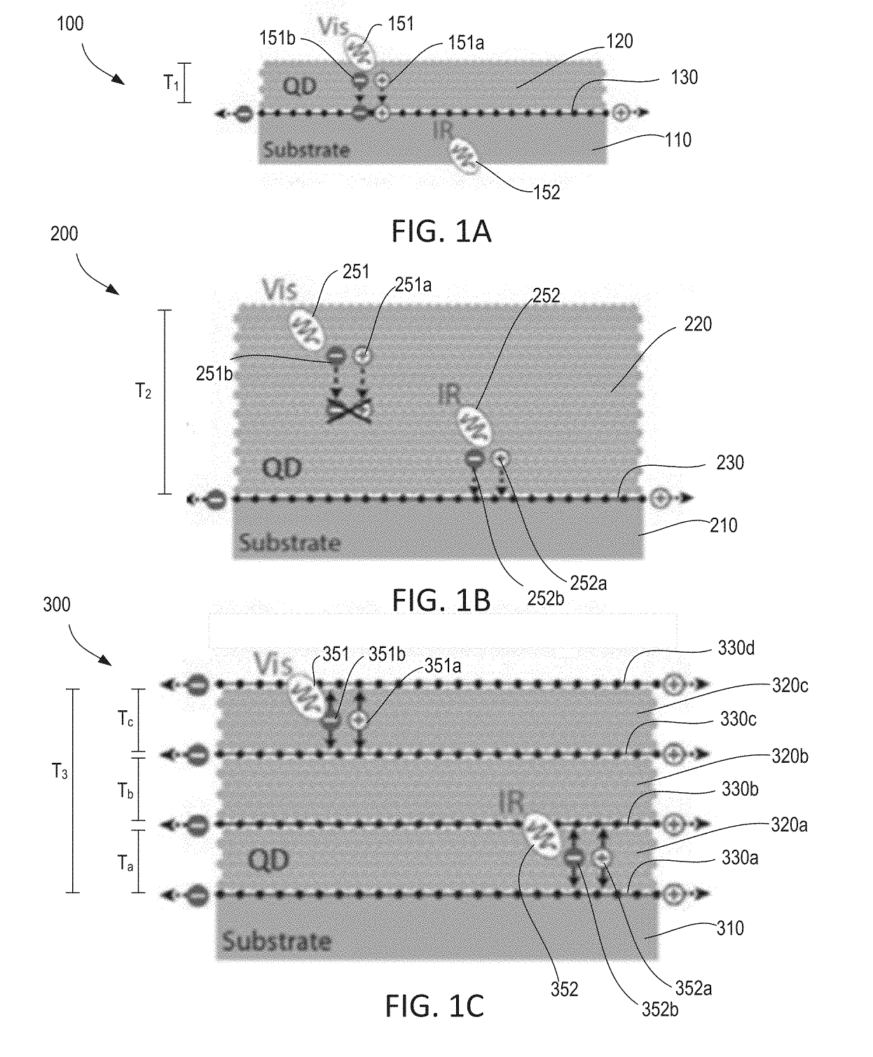

FIG. 1A shows a side view of an exemplary single Gr/QD architecture 100 have a thin single absorbing film with thickness <L_{D}˜200-300 nm The architecture 100 includes a substrate 110, a thin single absorbing layer, (e.g., semiconducting QDs) 120, with a thickness T₁, and a collector layer 130 between substrate 110 and absorbing layer 120. Electromagnetic radiation having a wavelength in the visible spectrum 151 has an absorption depth that is smaller than T₁ and generates charge carriers 151a and 151b at an origin in absorbing layer 120. Charge carriers 151a and 151b have a diffusion length greater than T₁ and can diffuse from their origin to a collector layer, such as collector layer 130 with a decreased probability of recombining. Electromagnetic radiation having a wavelength in the near IR 152 has an absorption depth that is greater than T₁. Without being bound by any particular theory, it is believed that films as in FIG. 1A have very efficient charge collection in the visible range, but their photoresponse is drastically reduced in the near infrared (IR; about 700 nm to about 1000 nm wavelengths), for which the absorption depth is larger than the thickness of some absorbing layers, resulting in poor light absorption despite high collection efficiency.

FIG. 1B illustrates a side view of an exemplary single Gr/QD architecture 200 having a thicker absorbing layer than the single Gr/QD architecture of FIG. 1A (e.g., thickness >L_{D}). The architecture 200 includes a substrate 210, an absorbing layer 220 with a thickness T₂, and a collector layer 230 between substrate 210 and absorbing layer 220. Electromagnetic radiation having a wavelength in the visible spectrum 251 has an absorption depth that is smaller than T₂ and generates charge carriers 251a and 251b at an origin in absorbing layer 220. Without wishing to be bound by theory, it is believed that charge carriers 251a and 251b have a diffusion length smaller than T₂ and therefore are likely to diffuse from their origin and recombine before reaching a collector layer, for example, collector layer 230. Electromagnetic radiation having a wavelength in the near IR 252 has an absorption depth that is smaller than T₂ and generates charge carriers 252a and 252b at an origin in absorbing layer 220. Charge carriers 252a and 252b have a diffusion length and position of origin such that at least some of charge carriers 252a and 252b are likely to diffuse through the absorbing layer 230 from their origin to a collector layer, such as collector layer 230, with a decreased probability of recombining. In this case, without being bound by any particular theory, the light absorption would be enhanced, but the collection efficiency would be decreased since some of the carriers would likely recombine before reaching the electrodes.

FIG. 1C illustrates a side view of an exemplary intercalated Gr/QD system composite film structure architecture 300. The architecture 300 includes a substrate 310 and absorbing layers 320a, 320b, and 320c; the absorbing layers can have thicknesses Tₐ, T_{b}, and T_{c}, respectively. Collector layer 330a is between the substrate 310 and absorbing layer 320a. Collector layer 330b is between absorbing layer 320a and absorbing layer 320b. Collector layer 330c is between absorbing layer 320b and absorbing layer 320c. Collector layer 330d is on top of absorbing layer 320c. Together, absorbing layers 320a, 320b, and 320c with collector layers 330a, 330b, 330c, and 330d have a thickness T₃. Electromagnetic radiation having a wavelength in the visible spectrum 351 has an absorption depth that is smaller than T₃ and can generate charge carriers 351a and 351b at an origin in absorbing layer 320c. Charge carriers 351a and 351b have a diffusion length greater than T_{c} and can diffuse from their origin to one of collector layers 330c or 330d with a decreased probability of recombining. Electromagnetic radiation having a wavelength in the near IR 352 has an absorption depth that is smaller than T₃ and can generate charge carriers 352a and 352b at an origin in absorbing layer 320a. Charge carriers 352a and 352b have a diffusion length greater than Tₐ and can diffuse from their origin to a collector layer, such as collector layer 330a or 330b with a decreased probability of recombining. Without being bound by any particular theory, it is believed that having the graphene layers spaced shorter than L_{D} allows for the total thickness of the combined absorbing layers to be thicker than the diffusion length while keeping high collection efficiency.

It should be appreciated that charge carriers 151a and 151b, 251a and 251b, 252a and 252b, 351a and 351b, and 352a and 352b are exemplary charge carriers and need not both be present in all embodiments. In some embodiments, a charge carrier can be an electron, a hole, or both.

In some embodiments of the disclosure, an absorbing layer can be made of an radiation-absorbing material. The absorbing material can be configured to absorb energy from electromagnetic radiation and consequently generate one or more charge carriers (e.g., electrons, holes, or both). A non-limiting example of an absorbing material configured in this way is a semiconductor. In some embodiments, the absorbing layer can be an absorbing layer material. In some embodiments, the L_{D} of a photocarrier of an absorbing material can be less than about 550 nm (e.g., less than about 450 nm, 400 nm, 350 nm, 300 nm, 250 nm, 200 nm, 150 nm, 100 nm, or 50 nm), or about 50 to 550 nm (e.g., 50 to about 100 nm, about 100 to about 150 nm, about 150 to about 200 nm, about 200 to about 250 nm, about 250 to about 300 nm, about 300 to about 350 nm, about 350 to about 400 nm, about 400 to about 450 nm, about 450 to about 500 nm, about 500 to about 550 nm, about 100 to about 200 nm, about 200 to about 300 nm, about 300 to about 400 nm, or about 400 to about 500 nm). In some embodiments, the absorbing material can be light (e.g., visible light, infrared light, UV light, and the like) absorbing semiconducting nanoparticles. In some embodiments, the absorbing material can be QDs. In some embodiments, the absorbing material can be a have an L_{D} of about 50 nm to about 500 nm (e.g., 50 nm to 100 nm, about 100 nm to about 200 nm, about 200 nm to about 300 nm, about 300 nm to about 400 nm, about 400 nm to about 500 nm, about 100 nm to about 300 nm, about 200 nm to about 400 nm, or about 300 nm to about 500 nm).

In some embodiments, a collector layer can be made of a two-dimensional atomic layer with high charge carrier mobility. A collector layer can be partially or fully transparent to electromagnetic radiation. In some embodiments of the disclosure, a collector layer can be made of graphene. In some embodiments, a collector can be made from one or more (e.g., 2, 3, 4, 5, 6, 7, 8, 9, 10, 20, or 50) layers of graphene. Graphene can also have properties such as having a band gap tunable at the Fermi level, high elasticity, an ambipolar field effect and a high mobility (e.g., 1000 cm²/V·s at room temperature).

In some embodiments, one or more absorbing layers can comprise quantum dots. Quantum dots useful in the absorbing layers of the disclosure can include a II-VI group compound semiconductor nanocrystal (e.g., two-element compounds such as CdSe, CdTe, ZnS, ZnSe, and ZnTe; three-element compounds such as CdSeS, CdSeTe, CdSTe, ZnSeS, ZnSeTe, ZnSTe, CdZnS, CdZnSe, and CdZnTe; four-element compounds, such as CdZnSeS, CdZnSeTe, CdZnSTe, CdHgSeS, CdHgSeTe, CdHgSTe, HgZnSeS, HgZnSeTe, and HgZnSTe), a III-V group compound semiconductor nanocrystal (e.g., two-element compounds such as GaN, GaP, GaAs, GaSb, InP, InAs, and InSb; three-element compounds such as GaNP, GaNAs, GaNSb, GaPAs, GaPSb, InNP, InNAs, InNSb, InPAs, InPSb, and GaAlNP; four-element compounds such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb), a IV-VI group compound semiconductor nanocrystal (e.g., two-element compounds such as PbS, PbSe, and PbTe; three-element compounds such as PbSeS, PbSeTe, PbSTe, SnPbS, SnPbSe, and SnPbTe; and four-element compounds, such as SnPbSSe, SnPbSeTe, and SnPbSTe), a IV group compound semiconductor nanocrystal (e.g., single-element compounds such as Si and Ge; and two-element compounds, such as SiC and SiGe), and mixtures thereof; and metal oxides, including ZnO, SiO₂, SnO₂, WO₃, ZrO₂, HfO₂, Ta₂O₅, BaTiO₃, BaZrO₃, Al₂O₃, Y₂O₃, ZrSiO₄, and mixtures thereof.

In some embodiments, one or more absorbing layers can comprise PbS nanocrystal quantum dots (also referred to as “PbS QDs” or “PbS nanoparticles”). PbS QDs have a size-tunable band gap, strong light absorption and low cost solution processing. However, the short diffusion length (about 200 nm) results in low charge collection efficiency that limits the photoresponsivity. In some embodiments, one or more absorbing layers can comprise ZnO nanocrystal quantum dots (also referred to as “ZnO QDs” or “ZnO nanoparticles”). In some embodiments, one or more absorbing layers can comprise CdSe nanocrystal quantum dots (also referred to as “CdSe QDs” or “CdSe nanoparticles”).

In some embodiments, an absorbing layer can have a thickness of about 2 nm to about 500 nm (e.g., about 2 to about 5 nm, about 5 to about 10 nm, about 10 to about 20 nm, about 20 to about 50 nm, about 50 to about 100 nm, about 100 to about 150 nm, about 150 to about 200 nm, about 200 to about 250 nm, about 250 to about 300 nm, about 300 to about 350 nm, about 350 to about 400 nm, about 400 to about 450 nm, about 450 to about 500 nm, about 10 to about 50 nm, or about 15 to about 30 nm). In some embodiments, an absorbing layer made of an absorbing material (e.g., semiconductor material) can have a thickness less than a diffusion length (e.g., less than 99%, 95%, 90%, 80%, 70%, 60%, 50%, 40%, 30%, 20%, or 10% of a diffusion length) of a photocarrier of the respective absorbing material.

In some embodiments, quantum dots can have an average diameter of about 2 nm to about 10 nm (e.g., about 2 to about 4 nm, about 4 to about 6 nm, about 6 to about 8 nm, about 3 to about 5 nm, about 5 to about 7 nm, or about 7 to about 9 nm).

In some embodiments, the absorbing layer includes 1 or more (e.g., 2, 3, 4, 5, 6, 7, 8, 9, or 10) layers of quantum dots.

In some embodiments, quantum dots can be formed according to any method known in the art, e.g., colloidal synthesis, chemical vapor diffusion, or a combination thereof. In some embodiments, quantum dots can be fabricated with oleic acid on the surface.

In some embodiments, the quantum dots can be formed into an absorbing layer by deposition on a collector layer (e.g, a graphene layer) or on a substrate. In some embodiments, the substrate can be an insulating material. In some embodiments, the substrate can be Si (e.g., 500 microns) and SiO₂ (e.g., 300 nm). In some embodiments, the substrate can be selected from the group consisting of Si, SiO₂, and combinations thereof. In some embodiments, a substrate can have a roughness of less than 5 nm; without being bound by any particular theory, it is believed that a roughness of less than 5 nm can aid in avoiding difficulties building the device. In some embodiments, deposition can be performed by any method known in the art, e.g., spin-coating, dipping, contact printing, ink-jetting, imprinting, or a combination thereof.

In some embodiments, the surface ligands of QDs can be modified by any method known in the art, e.g., as disclosed in Brown et. al., ACS Nano 2014 8 (6), 5863-5872, incorporated herein by reference. Without being bound by any particular theory, it is believed that surface ligand modification can increase production of photocarriers and/or increase the adhesion of the QDs to a substrate and/or adhesion of another material (e.g., a collector layer such as graphene) to a layer of QDs. In some embodiments, the surface ligands (e.g., oleic acid) of the QDs can be replaced, in full or in part, by EDT (1,2-Ethanedithiol) or TBAI (Tetrabutylammonium iodide). In some embodiments, surface ligand modification can alter the spacing of QDs on a substrate or collector layer. In some embodiments, surface ligand modification can improve transfer of charge carriers between quantum dots.

In some embodiments, a collector layer can be a graphene layer. In some embodiments, a collector layer can be a two-dimensional atomic graphene layer. In some embodiments, a graphene layer can be grown by any method known in the art, e.g., CVD or exfoliation. In some embodiments, a graphene layer can be deposited by any method known in the art, e.g., the wet method. Graphene can be advantageous, in some embodiments, by not having a significant effect on light absorption.

In some embodiments, a composite film structure incorporates intercalated collector (e.g., graphene) layers between absorbing layers. Without being bound by any particular theory, it is believed that intercalated collector layers can ensure faster and more efficient carrier collection to enhance the performance of a device, such as a photosensor, especially in the near-infrared range.

In some embodiments, a composite film structure can include alternating layers made of a material (e.g., absorbing layers made of absorbing material (e.g., QDs)) and a collector layer (e.g., a graphene layer). In some embodiments, a layer made out of a material can be configured to generate photocarriers when exposed to electromagnetic radiation. In some embodiments, a composite film structure can be disposed on a substrate (e.g., SiO₂, Si, or a combination thereof). In some embodiments, the first layer of a composite film structure (e.g., the layer that is in contact with the substrate) is an absorbing layer. In some embodiments, the first layer of a composite film structure (e.g., the layer that is in contact with the substrate) is a collector layer. In some embodiments, there can be at least 2 (e.g., at least 3, 4, 5, 6, 7, 8, 9, 10, 12, 14, 16, 18, or 20) absorbing layers. In some embodiments, there can be at least 1 (e.g., at least 2, 3, 4, 5, 6, 7, 8, 9, 10, 12, 14, 16, 18, or 20) collector layers.

In some embodiments, a composite film structure can include layers in an order of: a first absorbing layer, a first collector layer, and a second absorbing layer. In some embodiments, a composite film structure can include layers in an order of: a primary collector layer, a first absorbing layer, a first collector layer, and a second absorbing layer. In some embodiments, a composite film structure can include layers in an order of: a first absorbing layer, a first collector layer, a second absorbing layer, and a second collector layer. In some embodiments, a composite film structure can include layers in an order of: a primary collector layer, a first absorbing layer, a first collector layer, a second absorbing layer, and a second collector layer. In some embodiments, a composite film structure can include layers in an order of: a first absorbing layer, a first collector layer, a second absorbing layer, a second collector layer, and a third absorbing layer. In some embodiments, a composite film structure can include layers in an order of: a primary collector layer, a first absorbing layer, a first collector layer, a second absorbing layer, a second collector layer, and a third absorbing layer; FIG. 1C shows an exemplary composite film structure of this type. In some embodiments, a composite film structure can include layers in an order of: a first absorbing layer, a first collector layer, a second absorbing layer, a second collector layer, a third absorbing layer, and a third collector layer. In some embodiments, a composite film structure can include layers in an order of: a primary collector layer, a first absorbing layer, a first collector layer, a second absorbing layer, a second collector layer, a third absorbing layer, and a third collector layer.

In some embodiments, there can be at least two (e.g., at least 3, 4, 5, 6, 7, 8, 9, 10, 12, 14, 16, 18, or 20) absorbing layers, and at least two (e.g., at least 3, 4, 5, 6, 7, 8, 9, 10, 12, 14, 16, 18, or 20, as mathematically possible) of the absorbing layers are made of the same absorbing material. In some embodiments, there can be at least two (e.g., at least 3, 4, 5, 6, 7, 8, 9, 10, 12, 14, 16, 18, or 20) absorbing layers, and at least two (e.g., at least 3, 4, 5, 6, 7, 8, 9, 10, 12, 14, 16, 18, or 20, as mathematically possible) of the absorbing layers are made of different absorbing material. In some embodiments, there can be at least two (e.g., at least 3, 4, 5, 6, 7, 8, 9, 10, 12, 14, 16, 18, or 20) absorbing layers, and all of the absorbing layers are made of the same absorbing material. In some embodiments, there can be at least two (e.g., at least 3, 4, 5, 6, 7, 8, 9, 10, 12, 14, 16, 18, or 20) absorbing layers, and all of the absorbing layers are made of different absorbing material.

In some embodiments, there can be at least two (e.g., at least 3, 4, 5, 6, 7, 8, 9, 10, 12, 14, 16, 18, or 20) absorbing layers, and at least two (e.g., at least 3, 4, 5, 6, 7, 8, 9, 10, 12, 14, 16, 18, or 20, as mathematically possible) of the absorbing layers can have the same thickness. In some embodiments, there can be at least two (e.g., at least 3, 4, 5, 6, 7, 8, 9, 10, 12, 14, 16, 18, or 20) absorbing layers, and at least two (e.g., at least 3, 4, 5, 6, 7, 8, 9, 10, 12, 14, 16, 18, or 20, as mathematically possible) of the absorbing layers can have different thicknesses. In some embodiments, there can be at least two (e.g., at least 3, 4, 5, 6, 7, 8, 9, 10, 12, 14, 16, 18, or 20) absorbing layers, and all of the absorbing layers can have the same thickness. In some embodiments, there can be at least two (e.g., at least 3, 4, 5, 6, 7, 8, 9, 10, 12, 14, 16, 18, or 20) absorbing layers, and all of the absorbing layers can have different thicknesses.

In some embodiments, there can be at least two (e.g., at least 3, 4, 5, 6, 7, 8, 9, 10, 12, 14, 16, 18, or 20) absorbing layers made independently of absorbing material, and the thickness of each absorbing layer can be, independently, less than (e.g., less than 99%, 95%, 90% 80% 70%, 60%, 50%, 40%, 30%, 20% or 10%) of a diffusion length of the respective absorbing material.

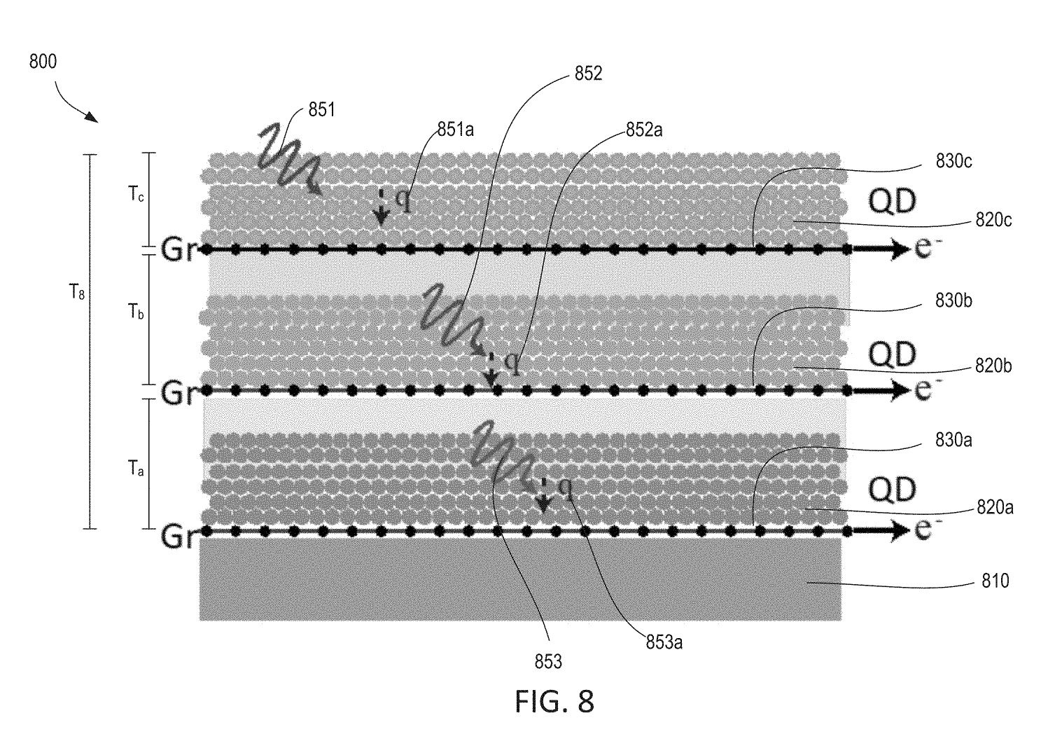

In some embodiments, the absorbing layer is made of QDs. In some embodiments, there can be at least two (e.g., at least 3, 4, 5, 6, 7, 8, 9, 10, 12, 14, 16, 18, or 20) absorbing layers, and at least two (e.g., at least 3, 4, 5, 6, 7, 8, 9, 10, 12, 14, 16, 18, or 20, as mathematically possible) of the absorbing layers are made of the same QDs. In some embodiments, there can be two (e.g., at least 3, 4, 5, 6, 7, 8, 9, 10, 12, 14, 16, 18, or 20) absorbing layers, and at least two (e.g., at least 3, 4, 5, 6, 7, 8, 9, 10, 12, 14, 16, 18, or 20, as mathematically possible) of the absorbing layers are made of different QDs. In some embodiments, there can be at least two (e.g., at least 3, 4, 5, 6, 7, 8, 9, 10, 12, 14, 16, 18, or 20) absorbing layers, and all of the absorbing layers are made of the same QDs. In some embodiments, there can be at least two (e.g., at least 3, 4, 5, 6, 7, 8, 9, 10, 12, 14, 16, 18, or 20) absorbing layers, and all of the absorbing layers are made of different QDs. For example, FIG. 8 shows an exemplary embodiment of a composite film structure with three absorbing layers, wherein each absorbing layer is made of different QDs. For example, a composite film structure can have a first absorbing layer of PbS QDs and a second layer of ZnO QDs. For example, a composite film structure can have a first absorbing layer of PbS QDs and a second layer of PbS QDs. For example, a composite film structure can have a first absorbing layer of PbS QDs, a second layer of CdSe QDs, and a third layer of ZnO QDs. For example, a composite film structure can have a first absorbing layer of PbS QDs, a second absorbing layer of PbS QDs, and a third absorbing layer of CdSe QDs. For example, a composite film structure can have a first absorbing layer of PbS QDs, a second absorbing layer of PbS QDs, a third absorbing layer of PbS QDs, and a fourth absorbing layer of PbS QDs.

In some embodiments, a composite film structure includes alternating n absorbing layers and m collector layers (e.g., graphene layers). In some embodiments, each of the m graphene layers is disposed (or “sandwiched”) between two of the n absorbing layers; in such embodiments, m=n−1. It will be appreciated that different layering regimes will lead to different relationships between n and m (e.g., m=n+1, m=n, or m=n−1) For example, in some embodiments, a composite film structure also includes a primary collector layer underneath the first of the n absorbing layers (e.g., between the first of the n absorbing layers and the substrate); in such embodiments, m=n. For example, in some embodiments, a composite film structure also includes a secondary collector layer on the n^{th} (e.g., if there are 5 absorbing layers, on the 5^{th}) absorbing layer (e.g., on the top of the composite film structure; in such embodiments m=n). In some embodiments, a composite film structure also includes a primary collector layer underneath the first of the n absorbing layers (e.g., between the first of the n absorbing layers and the substrate) and a secondary collector layer on the n^{th} (e.g., if there are 5 absorbing layers, on the 5^{th}) absorbing layer; in such embodiments, m=n+1. In some embodiments, n=2 or more (e.g., n=3, 4, 5, 6, 7, 8, 9, 10, 12, 14, 16, 18, or 20).

In some embodiments, a composite film structure includes from 1 to p collector (e.g., graphene) layers, each independently disposed between and directly contacting two absorbing layers. In some embodiments, p=1 or more (e.g., p=2, 3, 4, 5, 6, 7, 8, 9, 10, 12, 14, 16, 18, or 20).

In some embodiments, a composite film structure can include two or more semiconductor layers, with each semiconductor layer separated from other semiconductor layers by one or more collector layers, e.g., in the order of: optional primary graphene layer, first semiconductor layer, first collector layer, second collector layer, and so on, alternating collector layers and semiconductor layers. In some embodiments, each of the semiconductor layers can be chosen based on the wavelength(s) of light absorbed, yielding a ‘multicolor photodetector’.

FIG. 8 illustrates a side view of an exemplary multicolor photodetector architecture 800. The architecture 800 includes a substrate 810 and absorbing layers 820a, 820b, and 820c; the absorbing layers can have thicknesses Tₐ, T_{b}, and T_{c}, respectively. Collector layer 830a is between the substrate 810 and absorbing layer 820a. Collector layer 830b is between absorbing layer 820a and absorbing layer 820b. Collector layer 830c is between absorbing layer 820b and absorbing layer 820c. Collector layer 830d is on top of absorbing layer 820c. Together, absorbing layers 820a, 820b, and 820c with collector layers 830a, 830b, 830c, and 830d have a thickness T₈. Electromagnetic radiation having a first wavelength 851 has an absorption depth that is smaller than T_{c} and can generate charge carrier(s) 851a at an origin in absorbing layer 820c. Charge carrier(s) 851a have a diffusion length and position of origin such that at least some of charge carrier(s) 851a are likely to diffuse through the absorbing layer 820c from their origin to a collector layer, such as collector layer 830c, with a decreased probability of recombining. Electromagnetic radiation having a second wavelength 852 has an absorption depth that is greater than T_{c}, but less than the combined thickness of 820b, 820c, and 830c and can generate charge carrier(s) 852a at an origin in absorbing layer 820b. Charge carrier(s) 852a have a diffusion length and position of origin such that at least some of charge carrier(s) 852a are likely to diffuse through the absorbing layer 820b from their origin to a collector layer, such as collector layer 830b, with a decreased probability of recombining. Electromagnetic radiation having a third wavelength 853 has an absorption depth that is greater than the combined thickness of 820b, 820c, and 830c, but less than T₈ and can generate charge carrier(s) 853a at an origin in absorbing layer 820a. Charge carrier(s) 853a have a diffusion length and position of origin such that at least some of the charge carrier(s) 853a are likely to diffuse through the absorbing layer 820a from their origin to a collector layer, such as collector layer 830a, with a decreased probability of recombining.

In some embodiments, the semiconductor layers (intercalated by collector layers) in ‘multicolor photodetector’ can be ordered, relative to the substrate or primary collector layer, in the order of the wavelengths absorbed by the semiconductor layers, starting with the semiconductor layer that absorbs the longest wavelength(s) of light, followed by the semiconductor layer that absorbs the second longest wavelength(s) of light, and so on. For example, a layer of PbS quantum dots with a bandgap of 0.8 eV can be the first semiconductor layer, a layer of PbS quantum dots with a bandgap of 1.2 eV can be the second semiconductor layer, a layer of CdSe quantum dots with a bandgap of 1.7 eV can be the third semiconductor layer, and a layer of ZnO quantum with a bandgap of 3.5 eV can the fourth semiconductor layer, where each semiconductor layer is separated by a collector layer. It will be appreciated that other nanoparticle compositions and/or other nanoparticle sizes can be used in such a layering technique.

In some embodiments, composite film structures including Graphene+PbS quantum dots can be used for near infrared detection (e.g., nanoparticles having a bandgap of 1.2 eV, absorbing light with wavelength up to 1000 nm).

In some embodiments, composite film structures including Graphene+PbS quantum dots can be used for near infrared detections (e.g., nanoparticles having a bandgap of 0.8 eV, absorbing light with wavelength up to 1400 nm).

In some embodiments, composite film structures including Graphene+ZnO nanoparticles can be used for UV detection (e.g., nanoparticles having a bandgap of 3.5 eV, absorbing light with wavelength of 350 nm).

In some embodiments, composite film structures including Graphene+CdSe quantum dots for can be used for visible light detection (e.g., nanoparticles having a bandgap of 1.7 eV, absorbing light with wavelength up to 700 nm).

In some embodiments, a composite film structure can include a first absorbing layer made of PbS quantum dots (e.g., to absorb visible and/or near-IR light), a first collector layer (e.g., a graphene layer), and a second absorbing layer made of ZnO quantum dots (e.g., to absorb UV light). Such embodiments can further include a primary collector layer, disposed between the first absorbing layer and a substrate and/or a second collector layer, disposed on the second absorbing layer.

This disclosure also includes methods of forming composite film structures. Any of the composite film structures can be made by the methods disclosed herein or other methods known in the art. In some embodiments, a method of forming a composite film structure includes alternating deposition of an absorbing layer and a collector layer successively, starting on a substrate (e.g., SiO₂, Si, or a combination thereof). In some embodiments, the first layer formed on a substrate is an absorbing layer. In some embodiments, the first layer formed on a substrate is a collector layer.

In some embodiments, 1 or more (e.g., 2, 3, 4, 5, 6, 7, 8, 9, 10, 12, 14, 16, 18, or 20) of the absorbing layers is made of quantum dots. Quantum dots can be formed according to any method known in the art, e.g., colloidal synthesis, chemical vapor diffusion, or a combination thereof. In some embodiments, deposition of quantum dots can by performed by any method known in the art, e.g., spin-coating, dipping, contact printing, ink-jetting, imprinting, or a combination thereof. In some embodiments, quantum dots can be fabricated with oleic acid on the surface.

In some embodiments, 1 or more (e.g., 2, 3, 4, 5, 6, 7, 8, 9, 10, 12, 14, 16, 18, or 20) of the collecting layers is made of graphene. In some embodiments, a graphene layer can be deposited by any method known in the art, e.g., the wet method.

In some embodiments, a composite film structure may have a channel length of e.g., about 2 mm, about 1.5 mm, about 1 mm, about 0.5 mm, about 0.25 mm, 0.10 mm, or 0.05 mm. Without being bound by any particular theory, it is believed that decreasing the channel length will increase performance, as shown in FIG. 7. In some embodiments, a composite film structure may have a width of, e.g., about 3 mm, about 2 mm, or about 1 mm.

In some embodiments, intercalated devices show a drastic performance compared with non-intercalated structures. Without being bound by any particular theory, this is believed to be due to a much more efficient charge collection through graphene layers distributed through the entire thickness of the film, ensuring that photocarriers generated in the QD upon light absorption are collected efficiently. This approach can be used not only for quantum dots, but for any system limited by short diffusion lengths. This approach in particular can enhance light absorption in the infrared range, which can have deeper penetration depths.

This disclosure also includes photodetectors including composite film structures. A photodetector can include any of the composite film structures disclosed herein. In some embodiments, a photodetector includes at least 1 (e.g., at least 2, 3, 4, 5, 6, 7, 8, 9, 10, 12, 14, 16, 18, or 20) collector layers, and at least 1 (e.g., at least 2, 3, 4, 5, 6, 7, 8, 9, 10, 12, 14, 16, 18, or 20, as mathematically possible) of the collector layers is configured to be a current extractor. In some embodiments, a photodetector includes at least 2 (e.g., at least 3, 4, 5, 6, 7, 8, 9, 10, 12, 14, 16, 18, or 20) collector layers, and at least 2 (e.g., at least 3, 4, 5, 6, 7, 8, 9, 10, 12, 14, 16, 18, or 20, as mathematically possible) of the collector layers are configured to be a to operate as parallel conductive channels. In some embodiments, a photodetector can be configured to operate in a low bias regime. In some embodiments, a photodetector has a sensitivity of at least 1×10⁷ A/W at an irradiation of 1×10⁻⁵ mW/cm².

This disclosure also includes methods of fabricating photodetectors. Any of the photodetectors described herein can be fabricated by the methods disclosed herein. A method of fabricating a photodetector can include any of the methods of fabricating composite film structures described herein. In some embodiments, a method of fabricating a photodetector can further include configuring 1 or more (e.g., 2, 3, 4, 5, 6, 7, 8, 9, 10, 12, 14, 16, 18, or 20) of the collector (e.g., graphene) layers to be current extractors. In some embodiments, a method of fabricating a photodetector can further include configuring 1 or more (e.g., 2, 3, 4, 5, 6, 7, 8, 9, 10, 12, 14, 16, 18, or 20) of the collector (e.g., graphene) to be parallel conductive channels.

1. Sargent, E. H. Colloidal quantum dot solar cells. Nat. Photonics 6, 133-135 (2012).

2. Konstantatos, G. & Sargent, E. H. Nanostructured materials for photon detection. Nat. Nanotechnol. 5, 391-400 (2010).

3. Konstantatos, G. & Sargent, E. H. Colloidal quantum dot photodetectors. in Infrared Physics and Technology 54, 278-282 (2011).

4. Lan, X., Masala, S. & Sargent, E. H. Charge-extraction strategies for colloidal quantum dot photovoltaics. Nat. Mater. 13, 233-40 (2014).

5. Tang, J. & Sargent, E. H. Infrared colloidal quantum dots for photovoltaics: Fundamentals and recent progress. Adv. Mater. 23, 12-29 (2011).

6. Johnston, K. W. et al. Efficient Schottky-quantum-dot photovoltaics: The roles of depletion, drift, and diffusion. Appl. Phys. Lett. 92, (2008).

7. Carey, G. H., Levina, L., Comin, R., Voznyy, O. & Sargent, E. H. Record Charge Carrier Diffusion Length in Colloidal Quantum Dot Solids via Mutual Dot-To-Dot Surface Passivation. Advanced Materials (2015). doi:10.1002/adma.201405782

8. Koleilat, G. I. et al. Efficient, stable infrared photovoltaics based on solution-cast colloidal quantum dots. ACS Nano 2, 833-840 (2008).

9. Moreels, I. et al. Size-dependent optical properties of colloidal PbS quantum dots. ACS Nano 3, 3023-3030 (2009).

10. Clifford, J. P. et al. Fast, sensitive and spectrally tuneable colloidal-quantum-dot photodetectors. Nat. Nanotechnol. 4, 40-44 (2009).

11. Law, M. et al. Determining the internal quantum efficiency of PbSe nanocrystal solar cells with the aid of an optical model. Nano Lett. 8, 3904-3910 (2008).

12. Konstantatos, G. et al. Ultrasensitive solution-cast quantum dot photodetectors. Nature 442, 180-183 (2006).

13. Clifford, J. P. et al. Fast, sensitive and spectrally tuneable colloidal-quantum-dot photodetectors. Nat. Nanotechnol. 4, 40-44 (2009).

14. Lan, X. et al. 10.6% certified colloidal quantum dot solar cells via solvent-polarity-engineered halide passivation. Nano Lett. 16, 4630-4634 (2016).

15. Chuang, C.-H. M., Brown, P. R., Bulović, V. & Bawendi, M. G. Improved performance and stability in quantum dot solar cells through band alignment engineering. Nat. Mater. 13, 1-6 (2014).

16. Konstantatos, G. et al. Hybrid graphene-quantum dot phototransistors with ultrahigh gain. Nature Nanotechnology 7, 363-368 (2012).

17. Kufer, D. et al. Hybrid 2D-0D MoS 2-PbS Quantum Dot Photodetectors. Adv. Mater. n/a-n/a (2014). doi:10.1002/adma.201402471

18. Kufer, D., Lasanta, T., Bernechea, M., Koppens, F. H. L. & Konstantatos, G. Interface Engineering in Hybrid Quantum Dot-2D Phototransistors. ACS Photonics 3, 1324-1330 (2016).

19. Adinolfi, V. & Sargent, E. H. Photovoltage field-effect transistors. Nature (2017). doi:10.1038/nature21050

20. Sun, Z. et al. Infrared photodetectors based on CVD-grown graphene and PbS quantum dots with ultrahigh responsivity. Adv. Mater. 24, 5878-5883 (2012).

21. Nikitskiy, I. et al. Integrating an electrically active colloidal quantum dot photodiode with a graphene phototransistor. Nat. Commun. 7, 11954 (2016).

A number of embodiments of the invention have been described. Nevertheless, it will be understood that various modifications may be made without departing from the spirit and scope of the invention. Accordingly, other embodiments are within the scope of the following claims.

### Exemplary Embodiments

Embodiment 1 is a composite film structure, the composite film structure comprising:
   a first absorbing layer comprising a first material;
   a second absorbing layer comprising a second material; and
   a first collector layer disposed between the first absorbing layer and the second absorbing layer;
   wherein the first absorbing layer has a thickness that is less than a diffusion length of a photocarrier of the first material, and
   wherein the second absorbing layer has a thickness that is less than a diffusion length of a photocarrier of the second material.
Embodiment 2 is the composite film structure of embodiment 1, wherein at least one of the first material and the second material is configured to generate photocarriers when exposed to electromagnetic radiation.
Embodiment 3 is the composite film structure of embodiment 1, wherein at least one of the first material and the second material comprises quantum dots.
Embodiment 4 is the composite film structure of embodiment 3, wherein the quantum dots comprise PbS nanoparticles.
Embodiment 5 is the composite film structure of embodiment 3, wherein the quantum dots comprise ZnO nanoparticles.
Embodiment 6 is the composite film structure of embodiment 3, wherein the quantum dots comprise CdSe nanoparticles.
Embodiment 7 is the composite film structure of embodiment 1, wherein the first material comprises PbS nanoparticles and the second material comprises ZnO nanoparticles.
Embodiment 8 is the composite film structure of embodiment 1, wherein the diffusion length of a photocarrier of at least one of the first material and the second material is about 200 to about 300 nm.
Embodiment 9 is the composite film structure of embodiment 1, wherein the thickness at least one of the first absorbing layer and the second absorbing layer is about 5 to about 500 nm.
Embodiment 10 is the composite film structure of embodiment 9, wherein the thickness of at least one of the first absorbing layer and the second absorbing layer is about 15 to about 30 nm.
Embodiment 11 is the composite film structure of embodiment 1, wherein the first collector layer comprises graphene.
Embodiment 12 is the composite film structure of embodiment 1, wherein the first absorbing layer is disposed between the first collector layer and a primary collector layer.
Embodiment 13 is the composite film structure of embodiment 12, wherein the primary collector layer is disposed between the first absorbing layer and a substrate.
Embodiment 14 is the composite film structure of embodiment 13, wherein the primary collector layer comprises graphene.
Embodiment 15 is the composite film structure of embodiment 13, wherein the substrate is selected from the group consisting of SiO₂, Si, and combinations thereof.
Embodiment 16 is the composite film structure of embodiment 1, wherein the first material and the second material are the same material.
Embodiment 17 is the composite film structure of embodiment 1, wherein the first material and the second material are different materials.
Embodiment 18 is the composite film structure of embodiment 1, wherein the second absorbing layer is disposed between the first collector layer and a second collector layer.
Embodiment 19 is the composite film structure of embodiment 18, wherein the second collector layer is disposed between the second absorbing layer and a third absorbing layer comprising a third material, and wherein the third collector layer has a thickness that is less than the diffusion length of a photocarrier of the third material.
Embodiment 20 is the composite film structure of embodiment 19, wherein the diffusion length of a photocarrier of the third material is about 200 to about 300 nm.
Embodiment 21 is the composite film structure of embodiment 19, wherein the thickness of the third absorbing layer is about 5 to about 500 nm.
Embodiment 22 is the composite film structure of embodiment 19, wherein the thickness of the third absorbing layer is about 15 to about 30 nm.
Embodiment 23 is the composite film structure of embodiment 1, further comprising:
   a second absorbing layer;
   n absorbing layers each independently comprising a third material; and
   m collector layers,
   wherein the second collector layer is disposed between the second absorbing layer and the a first of the n absorbing layers,
   wherein the n absorbing layers and the m collector layers are alternatingly disposed such that each of the m collector layers is positioned between and directly contacting two absorbing layers,
   wherein each of the n absorbing layers independently has a thickness that is less than a diffusion length of a photocarrier of the respective third material,
   wherein n equals at least 1,
   wherein m equals n−1, and
   wherein n is less than or equal to 20.
Embodiment 24 is the composite film structure of embodiment 23, wherein the first material, the second material, the third material, or combinations thereof are configured to generate photocarriers when exposed to electromagnetic radiation.
Embodiment 25 is the composite film structure of embodiment 23, wherein two or more of the n absorbing layers comprise different materials.
Embodiment 26 is the composite film structure of embodiment 23, wherein two or more of the n absorbing layers comprise the same material.
Embodiment 27 is the composite film structure of embodiment 23, wherein all of the n absorbing layers comprise the same material.
Embodiment 28 is the composite film structure of embodiment 23, wherein one or more of the m collector layers comprise graphene.
Embodiment 29 is the composite film structure of embodiment 23, wherein the first material, the second material, the third material, or combinations thereof comprise quantum dots.
Embodiment 30 is the composite film structure of embodiment 29, wherein the quantum dots comprise PbS nanoparticles.
Embodiment 31 is the composite film structure of embodiment 29, wherein the quantum dots comprise ZnO nanoparticles.
Embodiment 32 is the composite film structure of embodiment 29, wherein the quantum dots comprises CdSe nanoparticles.
Embodiment 33 is the composite film structure of embodiment 23, wherein the diffusion length of a photocarrier of the first material, the second material, the third material, or combinations thereof is about 200 to about 300 nm.
Embodiment 34 is the composite film structure of embodiment 23, wherein the thickness of the each of the n absorbing layers, independently, is about 5 to about 500 nm.
Embodiment 35 is the composite film structure of embodiment 34, wherein the thickness of each of then layers, independently, is about 15 to about 30 nm.
Embodiment 36 is a photodetector comprising the composite film structure of embodiment 1, wherein the first collector layer is configured to be a current extractor.
Embodiment 37 is the photodetector of embodiment 36, wherein the photodetector is configured to operate in a low bias regime.
Embodiment 38 is the photodetector of embodiment 36, wherein the second absorbing layer is disposed between the first collector layer and a second collector layer.
Embodiment 39 is the photodetector of embodiment 36, wherein the first collector layer and the second collector layer are configured to operate as parallel conductive channels
Embodiment 40 is the photodetector of embodiment 39, wherein at least one of the first collector layer and the second collector layer comprises graphene.
Embodiment 41 is the photodetector of embodiment 36, wherein the first absorbing layer is disposed between the first collector layer and a primary collector layer.
Embodiment 42 is the photodetector of embodiment 41, wherein the first collector layer, the second collector layer, and the primary collector layer are configured to operate as parallel conductive channels.
Embodiment 43 is the composite film structure of embodiment 41, wherein the primary collector layer is disposed between the first absorbing layer and a substrate.
Embodiment 44 is the photodetector of embodiment 36, wherein the photodetector has a sensitivity of at least 1×10⁷ A/W at an irradiation of 1×10⁻⁵ mW/cm².
Embodiment 45 is the photodetector of embodiment 36, further comprising:
   a second collector layer
   n absorbing layers each independently comprising a third material; and
   m collector layers,
   wherein the second collector layer is disposed between the second absorbing layer and a first of the n absorbing layers,
   wherein the n absorbing layers and the m collector layers are alternatingly disposed such that each of the m collector layers is positioned between and directly contacting two absorbing layers,
   wherein the each of the n absorbing layers has a thickness that is less than a diffusion length of a photocarrier of the third material,
   wherein n equals at least 1,
   wherein m equals n, and
   wherein n is less than or equal to 20.
Embodiment 46 is a method of forming a composite film structure, the method comprising:
   spin-coating a first absorbing layer comprising a first material on a primary layer;
   transferring a first collector layer onto the first absorbing layer; and
   spin-coating a second absorbing layer comprising a second material on the first collector layer, wherein a thickness of the first absorbing layer of the first material is less than a diffusion length of a photocarrier of the first material, and a thickness of the second absorbing layer of the second material is less than a diffusion length of a photocarrier of the second material.
Embodiment 47 is the method of embodiment 46, further comprising transferring a second collector layer onto the second absorbing layer.
Embodiment 48 is the method of embodiment 46, wherein the primary layer is a primary collector layer.
Embodiment 49 is the method of embodiment 46, wherein the primary layer is a substrate.
Embodiment 50 is the method of embodiment 46, further comprising growing the first collector layer by chemical vapor deposition.
Embodiment 51 is the method of embodiment 46, wherein the thickness of one or more of the first absorbing layer and the second absorbing layer is about 5 to about 500 nm.
Embodiment 52 is the method of embodiment 51, wherein the thickness of one or more of the first absorbing layer and the second absorbing layer is about 15 to about 25 nm.
Embodiment 53 is the method of embodiment 46, further comprising modifying the first absorbing layer with surface ligand modification after the first absorbing layer is spin-coated on the primary layer.
Embodiment 54 is the method of embodiment 46, further comprising modifying the second absorbing layer with surface ligand modification after the second absorbing layer is spin-coated on the first graphene layer.
Embodiment 55 is the method of embodiment 46, wherein the at least one of first material and the second material comprises quantum dots.
Embodiment 56 is the method of embodiment 55, wherein the quantum dots are selected from the group consisting of PbS nanoparticles, ZnO nanoparticles, or CdSe nanoparticles.
Embodiment 57 is a method of fabricating a photodetector, the method comprising forming the composite film structure according to embodiment 46, wherein the first collector layer is configured to be a current extractor.
Embodiment 58 is a method of fabricating a photodetector, the method comprising forming the composite film structure according to embodiment 47, and wherein the first collector layer and the second collector layer are configured to be current extractors.
Embodiment 59 is the method of embodiment 58, wherein the first collector layer and the second collector layer are configured as parallel conductive channels.
Embodiment 60 is a composite film structure, the composite film structure comprising:
   n absorbing layers each independently comprising a first material; and
   m collector layers,
   wherein the n absorbing layers and the m collector layers are alternatingly disposed such that each of the m collector layers is positioned between and directly contacting two absorbing layers,
   wherein each of the n absorbing layers independently has a thickness that is less than a diffusion length of a photocarrier of the respective first material,
   wherein n is at least 2,
   wherein m is n−1, and
   wherein n is less than or equal to 20.
Embodiment 61 is the composite film structure of embodiment 60, further comprising a primary layer, the n absorbing layers and m collector layers being disposed thereon.
Embodiment 62 is the composite film structure of embodiment 61, wherein the primary layer comprises a second material, and wherein the primary layer has a thickness that is less than a diffusion length of a photocarrier of the second material.
Embodiment 63 is the composite film structure of embodiment 61 wherein the primary layer comprises a substrate.
Embodiment 64 is the composite film structure of embodiment 63, wherein the substrate is selected from the group consisting of SiO₂, Si, and combinations thereof.
Embodiment 65 is a composite film structure, the composite film structure comprising:
   from 1 to 20 collector layers, each independently disposed between and directly contacting two absorbing layers,
   wherein each absorbing layer independently comprises a material, and
   wherein each absorbing layer has a thickness that is less than a diffusion length of a photocarrier of the respective material.
Embodiment 66 is a composite film structure, the composite film structure comprising:
   a first graphene layer;
   a first layer comprising a first material disposed on the first graphene layer; and
   a second graphene layer disposed on the first layer; wherein the first layer has a thickness that is less than a diffusion length of the first material.
Embodiment 67 is the composite film structure of embodiment 66, wherein the first material is configured to generate photocarriers when exposed to electromagnetic radiation.
Embodiment 68 is the composite film structure of embodiment 66, wherein the first material comprises quantum dots.
Embodiment 69 is the composite film structure of embodiment 67, wherein the quantum dots comprises PbS nanoparticles.
Embodiment 70 is the composite film structure of embodiment 66, wherein the diffusion length is about 200-300 nm.
Embodiment 71 is the composite film structure of embodiment 66, wherein the thickness of the first layer is about 20 nm.
Embodiment 72 is the composite film structure of embodiment 66, further comprising a second layer of the first material disposed on the second graphene layer, and the second layer has a thickness that is less than the diffusion length of the first material.
Embodiment 73 is a photodetector comprising the composite film structure of embodiment 1, wherein the first graphene layer and the second graphene layer are configured to be current extractors.
Embodiment 74 is the photodetector of embodiment 73, wherein the photodetector is configured to operate in a low bias regime.
Embodiment 75 is the photodetector of embodiment 73, further comprising a second layer of the first material disposed on the second graphene layer, and the second layer has a thickness that is less than the diffusion length of the first material.
Embodiment 76 is the photodetector of embodiment 75, wherein the photodetector has a sensitivity of at least 1×10⁷ A/W at an irradiation of 1×10⁻⁵ mW/cm².
Embodiment 77 is the photodetector of embodiment 75, wherein the first graphene layer and the second graphene layer are configured as parallel conductive channels.
Embodiment 78 is a method of forming a composite film structure, the method comprising:
   transferring a first layer of graphene onto a substrate;
   spin-coating a layer of a first material on the first layer of graphene; and
   transferring a second layer of graphene onto the layer of the first material, wherein a thickness of the layer of the first material is less than a diffusion length of the first material.
Embodiment 79 is the method of embodiment 78, further comprising growing the graphene by chemical vapor deposition.
Embodiment 80 is the method of embodiment 78, wherein the thickness of the layer of the first material is about 20 nm.
Embodiment 81 is the method of embodiment 78, further comprising surface ligand modification after the layer of the first material is spin-coated on the first layer of graphene.
Embodiment 82 is the method of embodiment 78, wherein the first material comprises quantum dots.
Embodiment 83 is the method of embodiment 82, wherein the quantum dots comprise PbS nanoparticles.
Embodiment 84 is a method of fabricating a photodetector, the method comprising forming the composite film structure according to embodiment 78, and wherein the first graphene layer and the second graphene layer are configured to be current extractors.
Embodiment 85 is the method of embodiment 84, wherein the graphene layers are configured as parallel conductive channels.

### EXAMPLES

### Methods

Devices with intercalated electrodes were fabricated by sequential deposition of quantum dots and graphene. The devices were fabricated on Si chips with a 280 nm thick silicon oxide layer with predefined electrodes deposited by shadow masks. The electrodes defined a conductive channel 1 mm long and 2 mm wide. Then graphene grown by chemical vapor deposition on copper was transferred to the substrate by conventional wet method. For QDs, PbS nanoparticles with band gap of 1.24 eV were used. They were deposited by spin coating from a toluene solution followed by surface ligand modification. Unless otherwise specified, each QD layer is about 20 nm thick, corresponding a single spin-coated layer. There was no patterning on the graphene or the QD layers.

Devices with up to 10 absorbing layers (e.g., QD layers) with intercalated graphene layers were fabricated, and evaluated against non-intercalated devices. Improved performance of intercalated devices over non-intercalated devices is shown in Examples below.

### Example 1

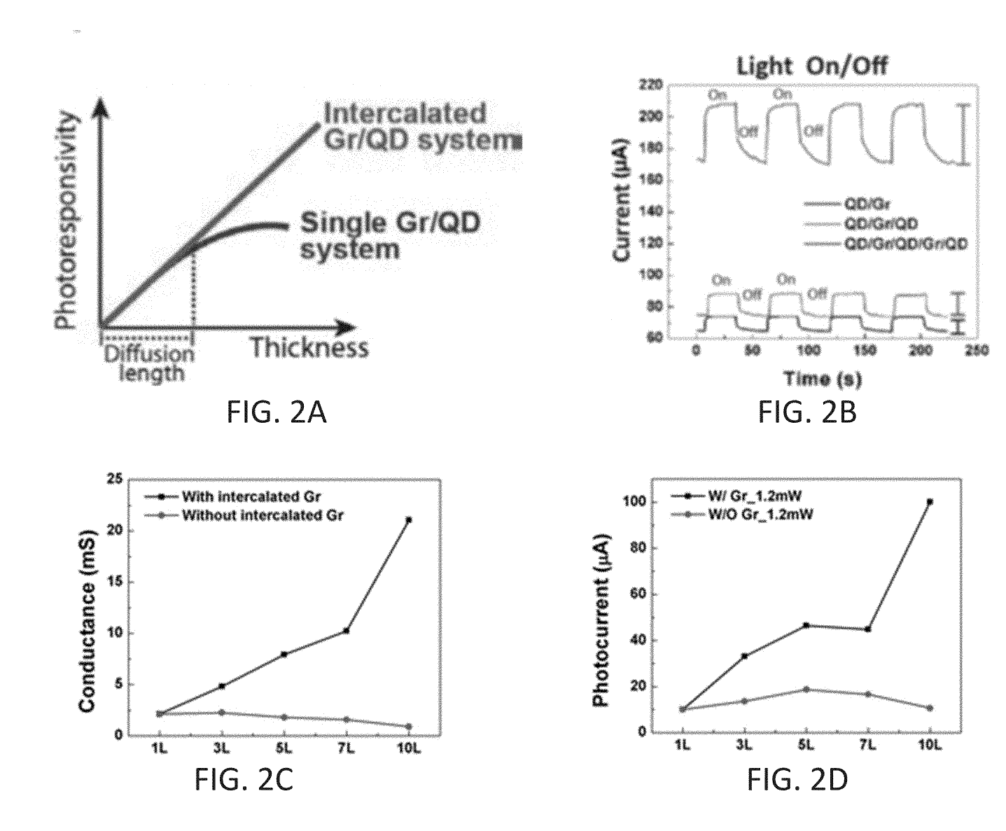

Devices were fabricated as in the methods section, and the properties of the devices was evaluated. FIG. 2A shows the theoretical performance of intercalated versus non-intercalated film structures with increasing total thickness; the performance of a non-intercalated films structure is expected to plateau in photoresponsivity after the thickness approaches the diffusion length of the material. FIG. 2B shows the performance evolution for the same device as QD and Gr layers were added. First, a QD layer was deposited, followed by the transfer of a Gr layer to obtain a QD/Gr device. The graphene was observed as a square with a darker color on the chip. The photoresponse (FIG. 2B) under a solar simulator with an AM 1.5 filter switched between ON/OFF states is shown with a dark current of 62 uA and a photocurrent response of 10 uA under 40 mV bias. Then, a second layer of QDs was added to obtain a QD/Gr/QD device. The dark current increased to 75 uA while the photoresponse also increased to 18 uA. A drastic change is observed when a second Gr and a third QD layer are added, obtaining a QD/Gr/QD/Gr/QD device. The dark current increased almost 2-fold, which is a consequence of now having two graphene conductive channels. Furthermore, the photoresponse also showed an increase of 30 uA. This change illustrates that adding graphene layers not only increases the conductivity of the hybrid Gr/QD device, but also enhances the photoresponse of the device, presumably by having an extra layer for photocharge collection.

FIGS. 2C and 2D show the evolution of conductivity and photoresponsivity for different devices, formed as above, with different number of QD layers with intercalated and non-intercalated graphene layers. In the case of intercalated devices, L stands for the number of QD layers. In the case of non-intercalated devices, L stands for the number of QD layers but with a single bottom graphene layer. FIG. 2C shows the steady increase in conductivity for the intercalated layers, whereas non-intercalated show basically a constant behavior. Furthermore, using a 1.2 mW/A, we also observe a significant increase in photoresponsivity for intercalated layers compared to non-intercalated devices. In the case of non-intercalated, we observe a slight increase when going from 1 to 5 layers, but then the response decreases. The intercalated device show a much larger responsivity that steady increases as we add more Gr/QD layers. These results show an enhanced photoresponsivity performance for intercalated devices over non-intercalated devices.

### Example 2

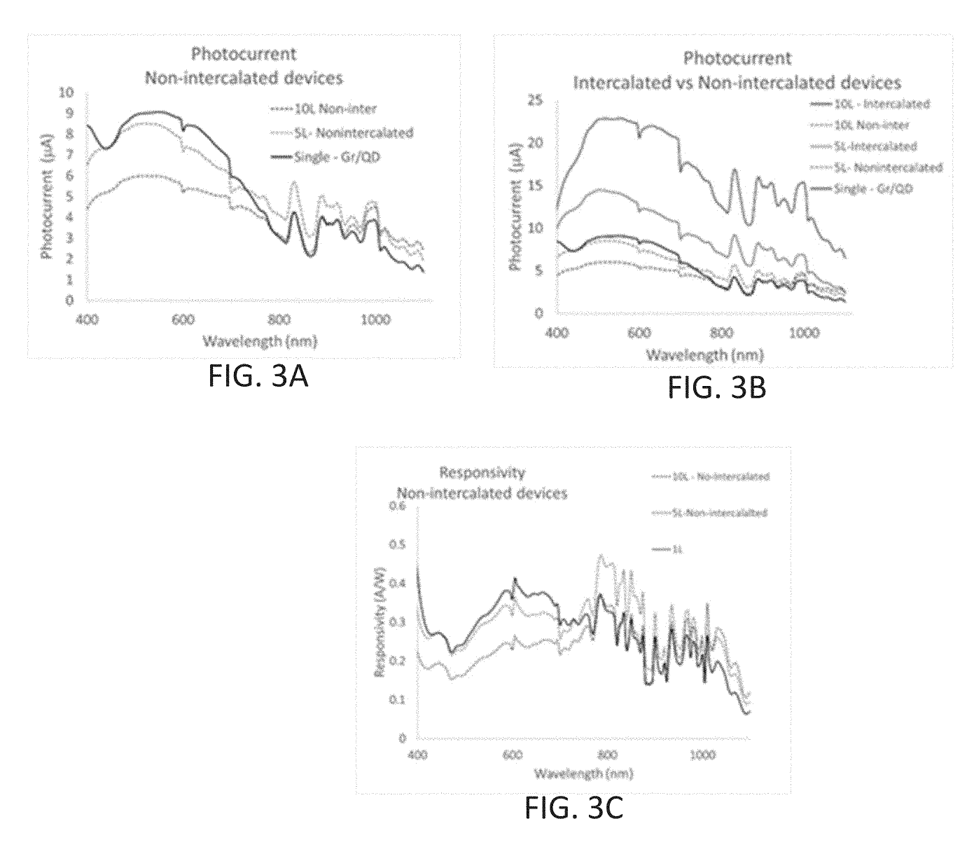

Devices were fabricated as in the methods section, and the spectral response of the devices was evaluated. FIG. 3 illustrates the spectral response of devices using a monochromator with a Xe lamp as source. FIG. 3A illustrates that for non-intercalated devices, the photocurrent in a device with 10 layers (10L; approximately 200 nm) is reduced for most wavelengths compared to a device with 1 layer (approximately 20 nm) of quantum dots. (Black and Red-dashed lines). For 5 layers (5L; approximately 100 nm) the response decreases in the visible range but increases in the near infrared range. In the visible range, the 1 and 5 layered QD devices give a higher response than the 10 QD device. Around a wavelength of 700 nm there is a significant reduction in the photocurrent for all the devices. Then, in the near-IR range there is a crossing and the 5L and 10L QD devices have a higher photocurrent compared to 1L QD device. This results shows the compromise when using a top/bottom electrode configurations. Thin layers are more efficient collecting charges, especially in the visible due to their 100 nm absorption depth. Increasing the thickness may enhance collection in the near-IR, but at the high cost of reduction the current collection from visible light.

FIG. 3B shows that data from FIG. 3A overlaid with data for intercalated devices, fabricated as above. Using intercalated layers, there is an increase in photocurrent from 1 to 10 layers of quantum dots. The increase is observed in the entire light wavelength range from 400 to 1000 nm.

The superior photocurrent of the intercalated response is evident across the entire 400-1200 nm range. In the case of 10 QD layers, the intercalated device has a photocurrent 4× times higher than the non-intercalated device. The higher photocurrent for the intercalated devices in the visible and IR indicates that the carriers are efficiently collected thorough the entire film. FIG. 3C shows the responsivity, i.e. photocurrent divided by incident light power, for the same devices as FIG. 3A, with similar behavior.

### Example 3

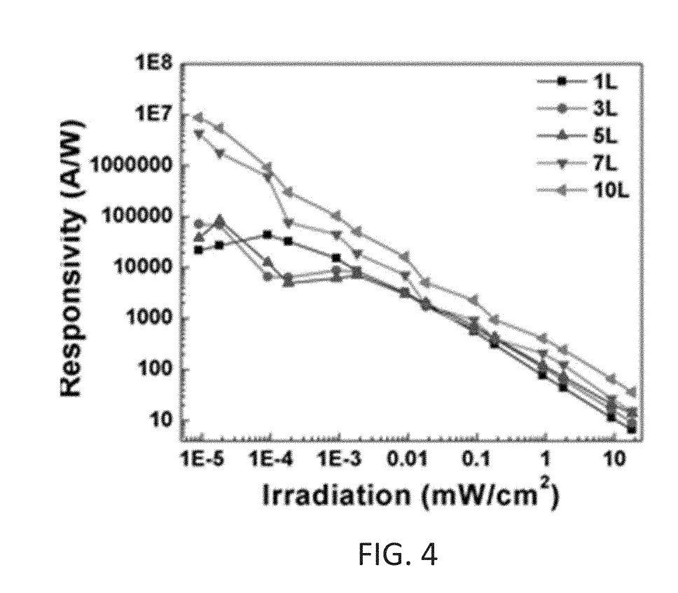

Intercalated devices with 1, 3, 5, 7, and 10 QD layers were fabricated as in the methods section, above. FIG. 4 illustrates the responsivity and incident power dependence of the fabricated devices. The responsivity increases for lower incident power reaching a 1E8 A/W for 1E-5 mW/cm² incident power.

### Example 4

Intercalated Gr/QD devices were made by sequential Gr wet transfer and QD spin coating on SiO2/Si substrate. High device conductivity was demonstrated, as each graphene adds an extra conductive channel, 10L intercalated Gr/QD devices have sheet resistance of 100 Ω/sq while the 10L device with single Gr sheet shows 2.2 k Ω/sq. Furthermore, an enhanced photoresponse was compared to single graphene devices, especially at near infrared spectral range (from 700 nm to 1100 nm). Single layer devices show a tradeoff between visible and near infrared response, whereas intercalated devices show much higher photoresponse in both ranges. For a 200 nm thick QD film under illumination with a 1.2 mW laser at 635 nm, the photocurrent of an intercalated Gr/QD device is 100 μA while the non-intercalated device gives a 10× lower response of 11 μA. These intercalated Gr/QD photodetectors can be operated in low bias regime with high photoresponse output, which is compatible with silicon integrated circuits.

### Example 5

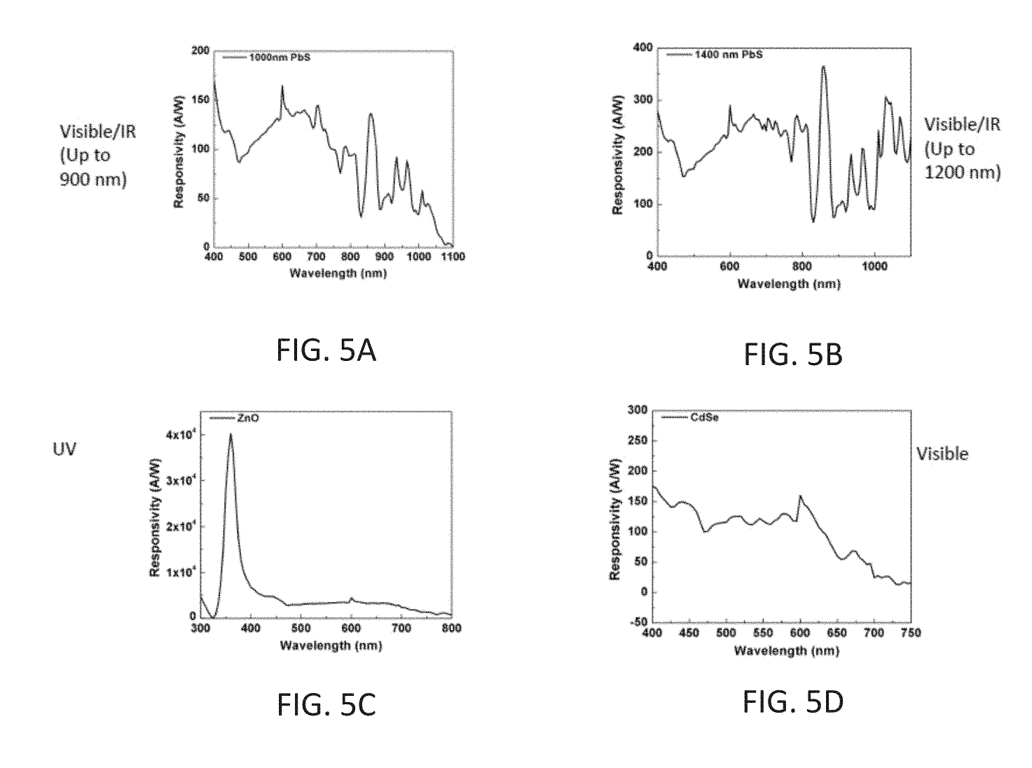

PbS nanoparticles were fabricated to a size that absorbs light up to wavelength λ of about 1000 nm light (“1000 nm PbS”), ant to a size that absorbs light up to wavelength λ of about 1400 nm (“1400 nm PbS”). Devices including these nanoparticles were fabricated as described in Example 1. The responsivity of these devices is shown in FIGS. 5A (λ of about 1000 nm light) and 5B (λ of about 1400 nm light). The device in FIG. 5B shows an improved responsivity at higher wavelengths compared to the device in FIG. 5A.

Devices were also fabricated using ZnO nanoparticles and CdSe nanoparticles, in a manner analogous to the methods section, above. The responsivity of these devices is shown in FIGS. 5C (ZnO nanoparticles) and 5D (CdSe nanoparticles). The device in 5C shows a high responsivity around 350 nm.

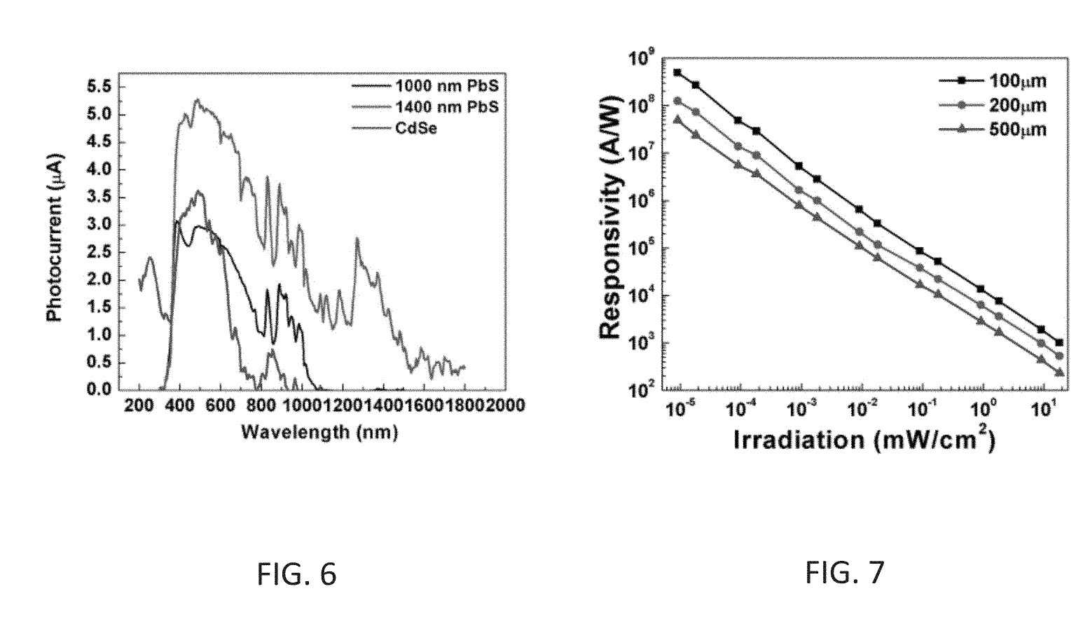

The photocurrent of the 1000 nm PbS nanoparticle devices, 1400 nm PbS nanoparticle devices, and CdSe nanoparticle devices was evaluated over a range of about 100 to about 2000 nm, as shown in FIG. 6. The 1400 nm PbS nanoparticle devices show an increased photocurrent across most wavelengths, as compared to the other devices.

### Example 6

Devices with channel lengths of 100 μm, 500 μm, and 1000 μm were fabricated as in Example 1, and the responsivity was evaluated, as shown in FIG. 7. The device with the shortest channel length (100 μm) displayed the greatest responsivity across all levels of irradiation intensity.

What is claimed is:

1. A composite film structure, the composite film structure comprising:
a first absorbing layer comprising a first material;
a second absorbing layer comprising a second material; and
a first collector layer disposed between the first absorbing layer and the second absorbing layer;
wherein the first absorbing layer has a thickness that is less than a diffusion length of a photocarrier of the first material, and
wherein the second absorbing layer has a thickness that is less than a diffusion length of a photocarrier of the second material.

2. The composite film structure of claim 1, wherein at least one of the first material and the second material comprises quantum dots.

3. The composite film structure of claim 1, wherein at least one of the first material and second material comprises quantum dots selected from PbS nanoparticles, ZnO nanoparticles, and CdSe nanoparticles.

4. The composite film structure of claim 1, wherein the thickness at least one of the first absorbing layer and the second absorbing layer is about 5 to about 500 nm.

5. The composite film structure of claim 1, wherein the first collector layer comprises graphene.

6. The composite film structure of claim 1, wherein the first absorbing layer is disposed between the first collector layer and a primary collector layer.

7. The composite film structure of claim 6, wherein the primary collector layer is disposed between the first absorbing layer and a substrate.

8. The composite film structure of claim 7, wherein the primary collector layer comprises graphene.

9. The composite film structure of claim 7, wherein the substrate is selected from the group consisting of SiO₂, Si, and combinations thereof.

10. The composite film structure of claim 1, wherein the first material and the second material are the same material.

11. The composite film structure of claim 1, wherein the first material and the second material are different materials.

12. The composite film structure of claim 1, further comprising:
a second absorbing layer;
n absorbing layers each independently comprising a third material; and
m collector layers,
wherein the second collector layer is disposed between the second absorbing layer and the a first of the n absorbing layers,
wherein the n absorbing layers and the m collector layers are alternatingly disposed such that each of the m collector layers is positioned between and directly contacting two absorbing layers,
wherein each of the n absorbing layers independently has a thickness that is less than a diffusion length of a photocarrier of the respective third material,
wherein n equals at least 1,
wherein m equals n−1, and
wherein n is less than or equal to 20.

13. The composite film structure of claim 12, wherein the thickness of the each of the n absorbing layers, independently, is about 5 to about 500 nm.

14. A photodetector comprising the composite film structure of claim 1, wherein the first collector layer is configured to be a current extractor.

15. The photodetector of claim 14, further comprising:
a second collector layer
n absorbing layers each independently comprising a third material; and
m collector layers,
wherein the second collector layer is disposed between the second absorbing layer and a first of the n absorbing layers,
wherein the n absorbing layers and the m collector layers are alternatingly disposed such that each of the m collector layers is positioned between and directly contacting two absorbing layers,
wherein the each of the n absorbing layers has a thickness that is less than a diffusion length of a photocarrier of the third material,
wherein n equals at least 1,
wherein m equals n, and
wherein n is less than or equal to 20.

16. A composite film structure, the composite film structure comprising:
n absorbing layers each independently comprising a first material; and
m collector layers,
wherein the n absorbing layers and the m collector layers are alternatingly disposed such that each of the m collector layers is positioned between and directly contacting two absorbing layers,
wherein each of the n absorbing layers independently has a thickness that is less than a diffusion length of a photocarrier of the respective first material,
wherein n is at least 2,
wherein m is n−1, and
wherein n is less than or equal to 20.

17. The composite film structure of claim 16, wherein two or more of then absorbing layers comprise different materials.

18. The composite film structure of claim 16, wherein two or more of then absorbing layers comprise the same material.

19. The composite film structure of claim 16, wherein all of then absorbing layers comprise the same material.

20. The composite film structure of claim 16, wherein one or more of the m collector layers comprise graphene.
